(19) United States
(12) Patent Application Publication
(10) Pub. No.: US 2007/0117259 A1
(43) Pub. Date: May 24, 2007

(54) Semiconductor component and method of manufacture

(75) Inventors: Harold G. Anderson, Chandler, AZ (US); Jay A. Yoder, Phoenix, AZ (US); Cang Ngo, Mesa, AZ (US); Joseph K. Fauty, Mesa, AZ (US); James P. Lettlerman JR., Mesa, AZ (US)

Correspondence Address: SEMICONDUCTOR COMPONENTS INDUSTRIES, LLC;BRADLEY J. BOTSCH, 5005 E. MCDOWELL ROAD, INTELLECTUAL PROPERTY DEPT. - A700, PHOENIX, AZ, 85008, US

(73) Assignee: Semiconductor Components Industries, LLC.

(21) Appl. No.: 11/281,160

(22) Filed: Nov. 18, 2005

(51) Int. Cl. H01L 21/00

(52) U.S. Cl. 438/106

(57) ABSTRACT

A circuit component having one or more encapsulated circuit elements that are not disposed on a rigid support substrate and a method for manufacturing the circuit component. A semiconductor wafer is disposed on a dicing film and singulated into individual semiconductor chips. The dicing film is stretched and a protective film is placed in contact with the active surfaces of the semiconductor chips. An encapsulating material is formed over the semiconductor chips. The encapsulating material covers the semiconductor chips and the portions of the protective film between the semiconductor chips to form a unitary structure. A support film is coupled to the unitary structure and the protective film is removed. The unitary structure is singulated into individual semiconductor components. Alternatively, multichip circuit components can be manufactured that may include active circuit elements, passive circuit elements, or combinations thereof.

### FIELD OF THE INVENTION

The present invention relates, in general, to semiconductor components and, more particularly, to semiconductor component packaging.

### BACKGROUND OF THE INVENTION

Semiconductor component manufacturers are constantly striving to increase the performance of their products while decreasing their cost of manufacture. A cost intensive area in the manufacture of semiconductor components is packaging the semiconductor chips that contain the semiconductor devices. As those skilled in the art are aware, discrete semiconductor devices and integrated circuits are fabricated from semiconductor wafers, which are then singulated or diced to produce semiconductor chips. Typically, one or more semiconductor chips is attached to a rigid support substrate and encapsulated within a mold compound so that the semiconductor chip is not exposed to an external ambient. This provides protection from environmental and physical stresses. In wafer-scale assembly technologies and in flip-chip technologies, solder bumps are formed on bonding pads that are present on the semiconductor wafer or the semiconductor chip. The semiconductor wafer or semiconductor chip is mounted to the support substrate so that the solder bumps can be bonded to corresponding bonding pads located on the support substrate. In addition to using flip-chip techniques, bonding may be performed using wire interconnects or a combination of flip-chip bonding and wire interconnects.

A drawback with these techniques is that in multi-chip packages a single defective bond can render the semiconductor component non-functional. Defective bonds can arise because of defects in the under-metal bump metallization system, cracks in the semiconductor material near the bonding pads, cratering, and failure of the solder joints because of the metal becoming fatigued. In addition, multi-chip packages generate large amounts of heat that can stress the semiconductor components if the heat is not removed. Another drawback is that in traditional wafer-scale and flip-chip technologies the bonding pads consume large amounts of semiconductor material. Moreover, these processing techniques are complex and expensive to implement in a manufacturing environment.

Hence, a need exists for a semiconductor component and a method of manufacturing the semiconductor component that allows for the production of single chip packages or multi-chip packages that are reliable and cost efficient to manufacture.

### BRIEF DESCRIPTION OF THE DRAWINGS

The present invention will be better understood from a reading of the following detailed description taken in conjunction with the accompanying drawing figures in which like reference characters designate like elements and in which:

FIG. 1 is a top view of a film frame, a film, and a semiconductor wafer used in the manufacture of a semiconductor component in accordance with an embodiment of the present invention;

FIG. 2 is a cross-sectional side view of the film frame, the film, and the semiconductor wafer of FIG. 1 taken along section line 2-2 after chip dicing or chip singulation;

FIG. 3 is a cross-sectional side view of the film and diced semiconductor wafer of FIG. 2 after stretching in accordance with an embodiment of the present invention;

FIG. 4 is a cross-sectional side view of the film and semiconductor wafer of FIG. 3 at a later stage of manufacture;

FIG. 5 is a cross-sectional side view of the film and semiconductor wafer of FIG. 4 at a later stage of manufacture;

FIG. 6 is a cross-sectional side view of a unitary structure comprising the singulated semiconductor wafer of FIG. 5 at a later stage of manufacture;

FIG. 7 is a cross-sectional side view of the unitary structure of FIG. 6 at a later stage of manufacture;

FIG. 8 is a cross-sectional side view of the unitary structure of FIG. 7 after package singulation;

FIG. 9 is a cross-sectional side view of a film frame, a film, and a semiconductor wafer after dicing in accordance with another embodiment of the present invention;

FIG. 10 is a cross-sectional side view of the unitary structure of FIG. 9 after singulation;

FIG. 11 is a cross-sectional side view of circuit elements mounted to a film in accordance with yet another embodiment of the present invention;

FIG. 12 is a cross-sectional side view of the circuit elements of FIG. 11 after mounting to another film in accordance with an embodiment of the present invention;

FIG. 13 is a cross sectional side view of a unitary structure comprising the circuit elements of FIG. 12 and an encapsulating material at a later stage of manufacture;

FIG. 14 is a cross-sectional side view of the unitary structure of FIG. 13 after the film has been removed from one surface of the unitary structure and an opposing surface of the unitary structure has been mounted to yet another film in accordance with an embodiment of the present invention; and

FIG. 15 is a cross-sectional side view of the unitary structure of FIG. 14 after package singulation.

### DETAILED DESCRIPTION

Generally, the present invention provides a circuit component and a method for manufacturing the circuit component that includes using a plurality of elastic films in supporting, dicing, and encapsulating circuit elements comprising the circuit component. The use of elastic films decreases the need for rigid support substrates such as, for example, metal leadframes, printed circuit boards, or the like. This lowers the manufacturing costs and decreases the complexity of manufacturing circuit components. In accordance with one embodiment, a bottom surface of a semiconductor wafer is mounted to a first elastic film and singulated into a plurality of semiconductor chips by, for example, sawing or cutting the semiconductor wafer. The first elastic film is stretched creating separation between the semiconductor chips and a second elastic film is attached to the top surfaces of the plurality of semiconductor chips. The first elastic film is removed from the bottom surfaces of the semiconductor chips. An encapsulating material is formed on the bottom surfaces and the side surfaces of the semiconductor chips to form a unitary structure having a bottom surface and a top surface. The second elastic film maintains the separation between semiconductor chips, protects the top or active surfaces of the semiconductor chips, and serves as a wall to form a top surface of the unitary structure, i.e., a top surface of the encapsulating material. The bottom surface of the unitary structure is mounted to a third elastic film and the unitary structure is singulated into individual circuit components. Although the semiconductor chips typically comprise active circuit elements such as, for example, insulated gate field effect transistors, bipolar junction transistors, insulated gate bipolar transistors, junction field effect transistors, or the like, they can comprise passive circuit elements such as resistors, capacitors, inductors, or the like. Alternatively, the semiconductor chips can be replaced with circuit elements derived from non-semiconductor based materials.

In accordance with another embodiment, the top surfaces of a plurality of circuit elements are placed in contact with an elastic film. The elastic film protects the top or active surfaces of the circuit elements and serves as a wall to form a top surface of the unitary structure, i.e., a top surface of the encapsulating material. The plurality of circuit elements are encapsulated using, for example, a mold compound to form a unitary structure having top and bottom surfaces. The bottom surface of the unitary structure is mounted to an elastic film and the elastic film contacting the circuit elements is removed thereby exposing the top surfaces of the unitary structure and the circuit elements. The unitary structure is singulated to form circuit components. It should be noted that each circuit component may be comprised of one or more circuit elements. Preferably, each circuit component has the same number and types of circuit elements.

It should be noted that adhesive films and tapes generally have a backing or carrier layer and an adhesive layer. The composition of each layer varies with tape type. For example, a wafer dicing film may have a polyester backing layer and either a silicone adhesive layer or an ultraviolet radiation (“UV”) curable layer. A package singulation tape may be comprised of, for example, a polyester backing with a silicone adhesive layer. However, the type of backing layer and adhesive layer are not limitations of the present invention.

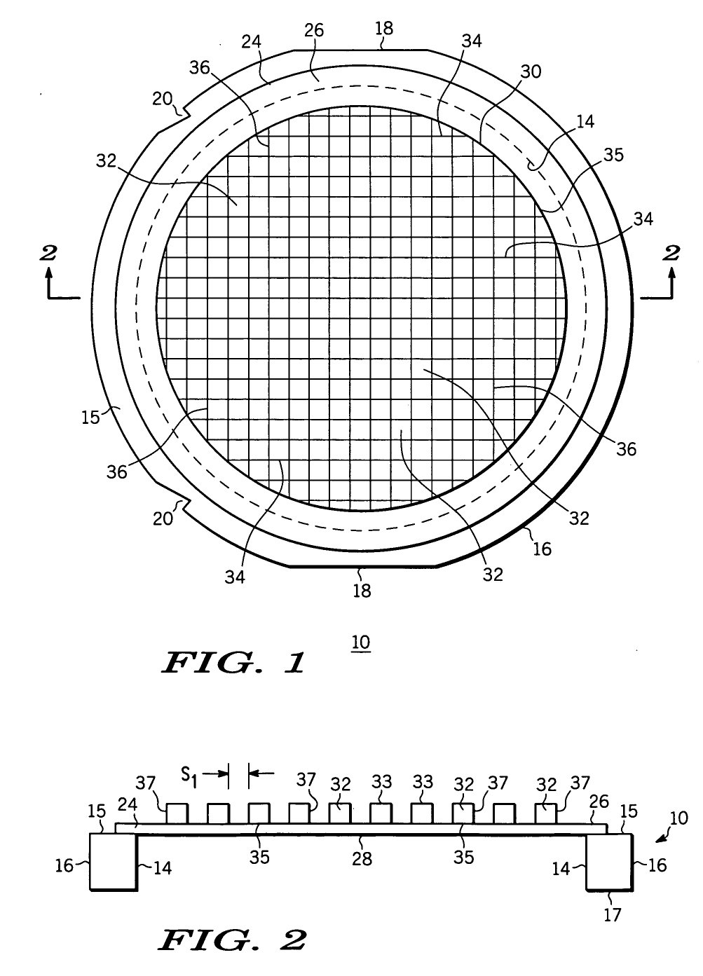

FIG. 1 is a top view of a film frame 10 used in the manufacture of a semiconductor component in accordance with an embodiment of the present invention. Film frame 10 has an annular shape with an inner edge 14 and an outer edge 16. Film frame 10 has top and bottom surfaces 15 and 17 (bottom surface 17 is shown in FIG. 2), respectively, a pair of flats 18 on opposing sides and a pair of positioning notches 20 for receiving guide pins (not shown). Film frame 10 is also referred to as a mounting frame assembly.

In operation, a film 24 having an adhesive surface 26 and a non-adhesive surface 28 is stretched across film frame 10 such that non-adhesive surface 28 contacts film frame 10. Suitable materials for film 24 include polyester, acrylic, polyimide, an ultraviolet sensitive film, a composite material, or the like. For the sake of clarity, surfaces 26, 28, 33, and 35 are discussed at this point, however, they are illustrated and further discussed with reference to FIG. 2. Film frame 10 and film 24 are mounted on a dicing machine (not shown) and fastened in place with mechanical clamps. Alternatively, film frame 10 and film 24 can be fastened in place using a vacuum, a combination of mechanical clamps and a vacuum, or the like. A substrate 30 such as, for example, a semiconductor wafer having top and bottom surfaces 33 and 35, respectively, and comprising a plurality of semiconductor chips or die 32 is mounted on adhesive surface 26. Preferably, top surface 33 of semiconductor wafer 30 includes a solderable top metal disposed on bonding pads, input-output pads, or the like. Examples of solderable top metals include a stacked layer of non-ferrous metals, a stacked layer of metal alloys, a conductive composite material, or the like. Even more particular examples of solderable top metals include, among others, a combination of titanium, nickel and silver; a combination of titanium, nickel, vanadium, and gold; a combination of titanium, tungsten, nickel, vanadium, and gold; a combination of chromium, nickel, and gold; and a combination of aluminum, chromium, nickel and gold. Semiconductor wafer 30 has a plurality of scribe lines 34 that are substantially parallel to each other and a plurality of scribe lines 36 that are substantially parallel to each other but substantially perpendicular to scribe lines 34. Scribe lines 34 cooperate with scribe lines 36 to form a scribe grid that forms a boundary of individual semiconductor chips or die 32. It should be understood that the type of substrate that is mounted to substrate 30 is not a limitation of the present invention. For example, the substrate can be a Ball Grid Array (BGA) substrate, a Pin Grid Array (PGA), or the like. The dicing machine cuts or saws substrate 30 along scribe lines 34 and 36 to form individual semiconductor chips 32 having sides 37. The process of cutting a substrate such as a semiconductor wafer 30 into individual elements is referred to as dicing or singulating the substrate.

FIG. 2 is a cross-sectional side view of film frame 10, film 24, and semiconductor wafer 30 taken along section line 2-2 of FIG. 1 after dicing. What is shown in FIG. 2 is inner edge 14, outer edge 16, top surface 15, and bottom surface 17 of film frame 10. Non-adhesive surface 28 of film 24 contacts top surface 15 of film frame 10. Dicing semiconductor wafer 30 separates it into individual semiconductor chips 32 which are laterally spaced apart or separated from each other by a distance S₁. Each semiconductor chip 32 has a top surface 33 and sides 37, wherein top surface 33 comprises a solderable metal disposed on bonding pads, input-output pads, or the like.

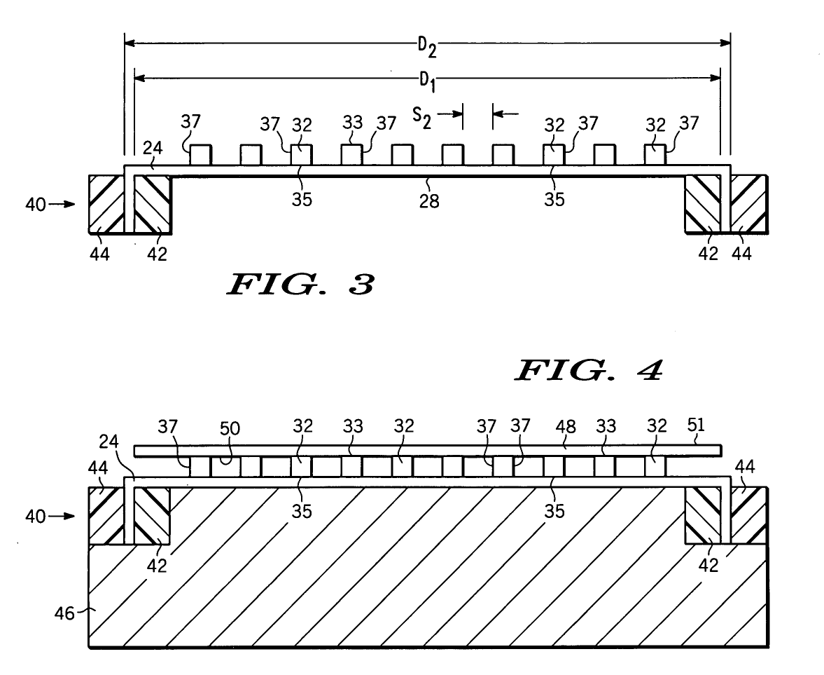

Referring now to FIG. 3, film 24 is stretched to increase the distance between adjacent semiconductor chips 32. In accordance with one embodiment, film 24 is stretched using a film stretcher 40 which may comprise a pair of concentric plastic hoops or rings 42 and 44. Alternatively, film stretcher 40 may be a semiautomated expander or a fully automated expander such as, for example, a motorized, lead-screw driven die bonder expander. Ring 42 has an outer diameter D₁ and ring 44 has an inner diameter D₂ which is larger than outer diameter D₁. Film 24 is stretched over ring 42 to increase the distance between adjacent semiconductor chips 32. After stretching, semiconductor chips 32 are laterally separated from each other by a distance S₂, which is greater than distance S₁. Hoop or ring 44 is frictionally fit around ring 42 such that portions of film 24 are between hoops or rings 42 and 44. Frictionally fitting hoop 44 around hoop 42 secures film 24 to film stretcher 40. It should be noted that the technique for stretching film 24 is not a limitation of the present invention.

Referring now to FIG. 4, film stretcher 40 and film 24 are mounted to a chuck 46. A film 48 having an adhesive surface 50 and a non-adhesive surface 51 is coupled to surfaces 33 of semiconductor chips 32. In particular, adhesive surface 50 contacts surfaces 33 of semiconductor chips 32. Suitable materials for film 48 include polyester, acrylic, a polyimide, an ultraviolet sensitive film, a composite material, or the like.

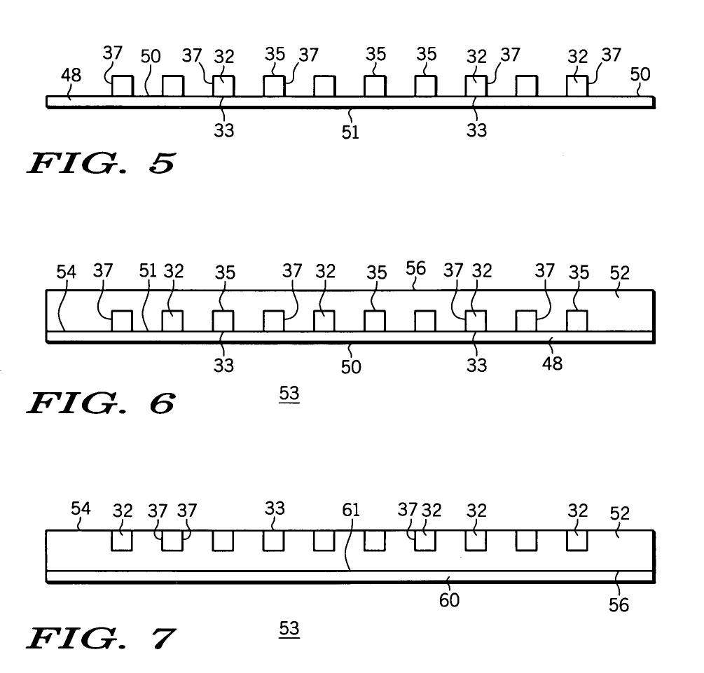

Referring now to FIG. 5, film stretcher 40 and films 24 and 48 are removed from chuck 46. Then, film 24 is removed from semiconductor chips 32. Thus, film 24 is separated from bottom surfaces 35 of semiconductor chips 32 leaving them exposed. It should be noted that film 48 is shown as being inverted relative to its position in FIG. 4.

Referring now to FIG. 6, exposed surfaces 35 and the regions between semiconductor chips 32 are covered with an encapsulating material 52 such as, for example, a mold compound to form a unitary structure 53 comprising the plurality of semiconductor chips 32 electrically isolated from each other by encapsulating material 52. Suitable encapsulating materials include epoxy novolac-based mold compounds, silicone-based mold compounds, or the like. Encapsulating material 52 covers surfaces 35 and sides 37 of semiconductor chips 32 and contacts non-adhesive surface 51. The mold material can be transfer-molded in a press or glob-topped with a dispensed paste, then cured. Preferably, encapsulating material 52 is an epoxy-novolac-based mold compound or a silicone-based mold compound that is a thermoset which is cured during the transfer molding process. However, it may be desirable to include post-mold curing. For a glob-topped paste, a post mold curing may be included wherein the glob-topped paste is cured by heating in a nitrogen ambient at a temperature ranging from about 125 degrees Celsius (° C.) to about 175° C. Encapsulating material 52 has a top surface 54 and a bottom surface 56.

Referring now to FIG. 7, bottom surface 56 of encapsulating material 52 is mounted on a top surface 61 of a film 60. By way of example, film 60 is the same type of film as film 24. The material of film 60 is not a limitation of the present invention. Suitable materials for film 60 include a polyester backing layer having a silicone adhesive layer, a polyester backing layer having an acrylic adhesive layer, a polyimide backing layer having a silicone adhesive layer, a polyimide backing layer having an acrylic adhesive layer, or the like. Film 48 is removed from unitary structure 53. It should be noted that unitary structure 53 is shown as being inverted relative to its position in FIG. 6.

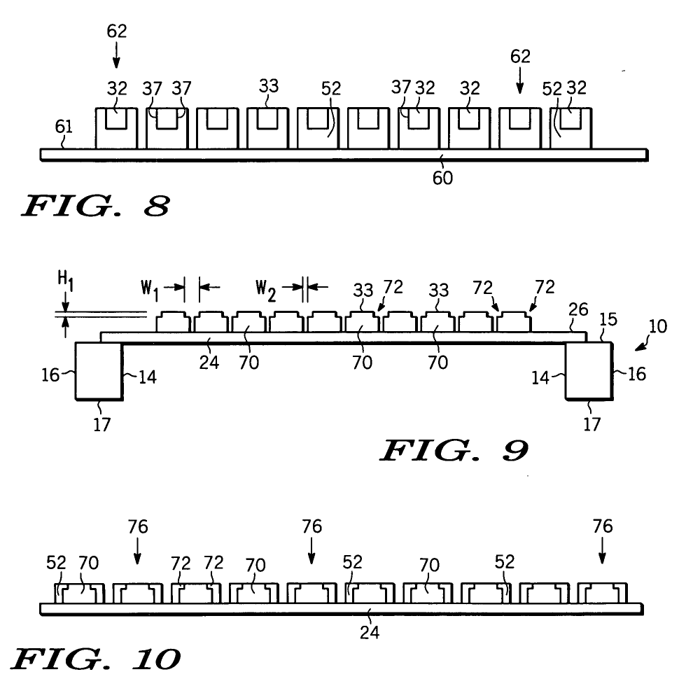

Referring now to FIG. 8, unitary structure 53 is singulated by sawing or cutting along the portions of encapsulating material 50 between semiconductor chips 32 to form individual semiconductor components 62. Singulation may be accomplished using a saw blade, water-jet cutting tool, a laser, a combination laser and water-jet cutting tool, or the like. In accordance with one embodiment, bottom surfaces 33 and sides 37 of semiconductor chips 32 are covered with encapsulating material. Each individual semiconductor component 62 is removed from film 60 using, for example, a pick and place tool and placed in a tape and reel or in a tray. The semiconductor components typically undergo a series of electrical tests to ensure they function properly. Semiconductor components 62 can be electrically coupled to other circuitry using techniques such as, for example, flip-chip mounting, wire bonding, solder reflow, or the like.

FIG. 9 is a cross-sectional side view of film frame 10, film 24, and semiconductor wafer 30 after dicing in accordance with another embodiment of the present invention. It should be noted that the description of dicing semiconductor wafer 30 with reference to FIG. 9 differs from that of FIG. 2 in that a double-pass cutting technique, is used to saw semiconductor wafer 30 shown in FIG. 9. More particularly, cuts are made into semiconductor wafer 30 along scribe lines 34 and 36 using a saw blade having a width W₁. The resulting cuts have a width W₁ and extend a distance H₁ into semiconductor wafer 30 from top surface 33. Then, cuts are made into semiconductor wafer 30 along scribe lines 34 and 36 using a saw blade having a width W₂, wherein width W₂ is less than width W₁. The resulting cuts have a width W₂ and extend to surface 26 of film 24 thereby forming semiconductor chips 70. Using the double-pass cutting technique creates notches 72 around the perimeters of semiconductor chips 70. It should be further noted that the dicing of semiconductor wafer 30 can be achieved using a unique saw blade configuration rather than a double-pass cutting technique. In other words, the saw blade can be configured to produce a cut having a portion with a width W₁ and extending a distance H₁ into semiconductor wafer 30 and having a portion with a width W₂.

Referring now to FIG. 10, film 24 is removed from film frame 10, stretched to increase the distance between adjacent semiconductor chips 70, encapsulated with an encapsulating material such as, for example, encapsulating material 52 to form a unitary structure, and sawed or cut to form individual semiconductor components 76. Techniques suitable for stretching film 24, encapsulating semiconductor chips 70 to form the unitary structure, and forming individual semiconductor components 76 from the unitary structure have been described with reference to FIGS. 3-8. A difference between semiconductor components 76 and semiconductor components 62 is the presence of notches 72 in semiconductor components 76. Notches 72 serve as locking features. For example, when the encapsulating material is a mold compound, notches 72 serve as mold locking features. Locking features promote adhesion of an encapsulant such as a mold compound to semiconductor chips 70. Locking features are also referred to as encapsulant adhesion-promotion features.

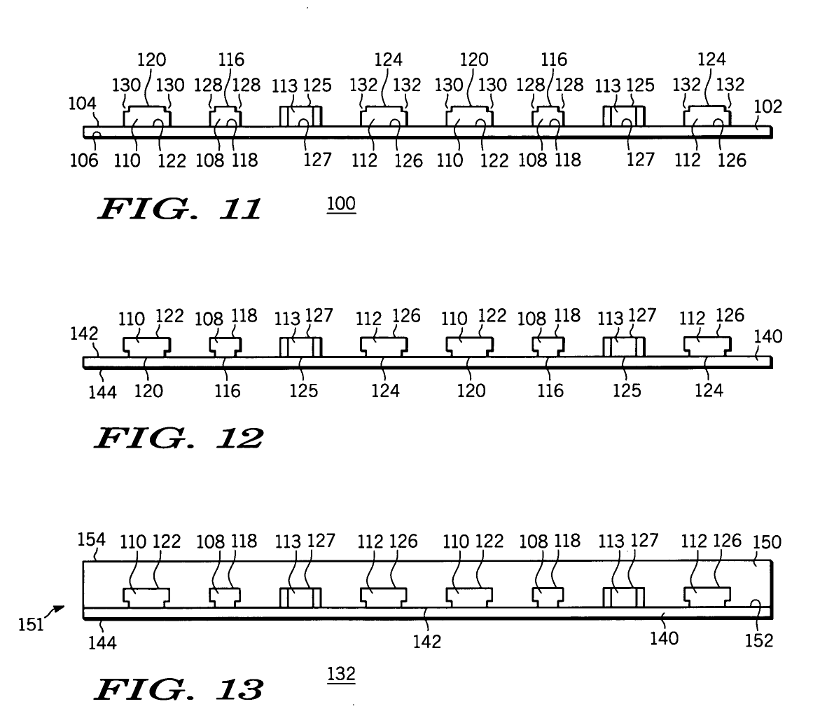

Referring now to FIG. 11, a side view of a multi-chip semiconductor component 100 at an intermediate stage of manufacture in accordance with another embodiment of the present invention is illustrated. What is shown in FIG. 11 is a film 102 on which a plurality of circuit elements is mounted. More particularly, logic circuit elements 108, analog circuit elements 110, discrete circuit elements 112, and passive circuit elements 113 are mounted to a top surface 104 of film 102. Logic circuit elements 108 have top and bottom surfaces 116 and 118, respectively, analog circuit elements 110 have top and bottom surfaces 120 and 122, respectively, discrete circuit elements 112 have top and bottom surfaces 124 and 126, respectively, and passive circuit elements 113 have top and bottom surfaces 125 and 127, respectively. Top surfaces 116, 120, 124, and 125 preferably include portions having a solderable metal disposed on bonding pads, input-output pads, or the like. It should be noted that the circuit elements may be singulated from a substrate such as, for example, a semiconductor wafer as was described with reference to FIGS. 1 and 2. It should be further noted that passive circuit elements 113 can be chip capacitors or chip resistors having electrically conductive material disposed on opposing ends.

Although not shown, a bottom surface 106 of film 102 may be mounted to a film frame such as film frame 10 or to a film stretcher such as film stretcher 40. In accordance with this embodiment, the circuit elements may be placed on film 102 after it has been stretched because the distance between the circuit elements can be set by the tool used to place the circuit elements on film 102. By way of example, the tool used to place circuit elements 108, 110, 112 and 113 on film 102 is a pick and place tool. Although circuit elements 108, 110, and 112 are shown as having notches 128, 130, and 132, respectively, it should be understood that this is not a limitation of the present invention and that the notches may be absent from the circuit elements or present in one or more of the circuit elements. Like notches 72 described with reference to FIG. 10, notches 128, 130, and 132 serve as locking features.

Referring now to FIG. 12, a film 140 having an adhesive surface 142 and a non-adhesive surface 144 is coupled to surfaces 116, 120, 124, and 125 of circuit elements 108, 110, 112, and 113, respectively. In particular, surfaces 116, 120, 124, and 125 of circuit elements 108, 110, 112, and 113, respectively, contact adhesive surface 142. Film 102 is removed from circuit elements 108, 110, 112, and 113, leaving surfaces 118, 122, 126, and 127 exposed. It should be noted that circuit elements 108, 110, 112, and 113 are shown as being inverted relative to their positions in FIG. 11.

Referring now to FIG. 13, exposed surfaces 118, 122, 126, and 127 and the regions between circuit elements 108, 110, 112, and 113 are covered with an encapsulating material 150 such as, for example, a mold compound, to form a unitary structure 151 comprising the plurality of circuit elements 108, 110, 112, and 113 and encapsulating material 150. Suitable encapsulating materials include epoxy novolac-based mold compounds, silicone-based mold compounds, or the like. Encapsulating material 150 covers surfaces 35 and sides 37 of semiconductor chips 32 and contacts adhesive surface 142. The mold material can be transfer-molded in a press or glob-topped with a dispensed paste, then cured. Preferably, encapsulating material 150 is an epoxy-novolac-based mold compound or a silicone-based mold compound that is a thermoset which is cured during the transfer molding process. However, it may be desirable to include post-mold curing. For a glob-topped paste, a post mold curing may be included wherein the glob-topped paste is cured by heating in a nitrogen ambient at a temperature ranging from approximately 125° C. to approximately 175° C. Encapsulating material 150 has a top surface 152 and a bottom surface 154.

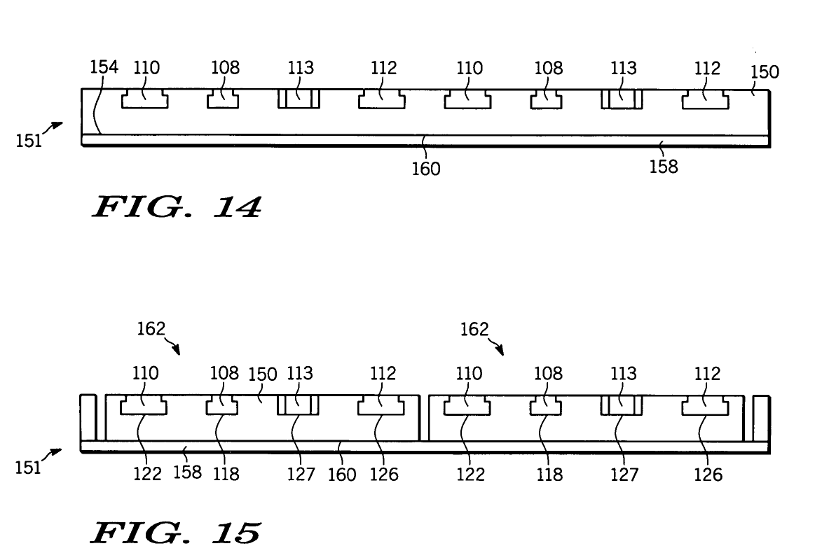

Referring now to FIG. 14, bottom surface 154 of encapsulating material 150 is mounted on a top surface 160 of a film 158. By way of example, film 158 is the same type of film as film 102. The material of film 158 is not a limitation of the present invention. Suitable materials for film 158 include a polyester backing layer with either silicone adhesive layer or an acrylic adhesive layer, a polyimide backing layer with either a silicone or an acrylic adhesive, or the like. Film 140 is removed from unitary structure 151. It should be noted that circuit elements 108, 110, 112, and 113 are shown as being inverted relative to their positions in FIG. 13.

Referring now to FIG. 15, unitary structure 151 is sawed along the portions of encapsulating material 150 between groups of circuit elements to form semiconductor components 162. Each semiconductor component 162 comprises a logic circuit element 108, an analog circuit element 110, a discrete circuit element 112, and a passive circuit element 113. Thus, semiconductor components 162 are multi-chip components or multi-chip modules. Each individual semiconductor component 162 can be removed from film 158 using, for example, a pick and place tool, and placed on a tape and reel or in a tray. The semiconductor components typically undergo a series of electrical tests to ensure that they function properly. The circuit elements within semiconductor components 162 can be electrically coupled to each other using techniques such as, for example, wire bonding, solder reflow, or the like. Similarly, the semiconductor components can be electrically coupled to circuitry external to the semiconductor component using techniques such as, for example, flip-chip mounting, wire bonding, solder reflow, or the like.

By now it should be appreciated that a method for manufacturing a semiconductor component that does not include mounting circuit elements to rigid support substrates such as a leadframe or a printed circuit board and a semiconductor component manufactured in accordance with the method have been provided. In accordance with an embodiment of the present invention, a single circuit element is embedded within an encapsulating material using a plurality of films to protect the active surface of the circuit element and to help shape the encapsulating material. In accordance with another embodiment of the present invention, a plurality of circuit elements are embedded within an encapsulating material using a plurality of films to protect their active surfaces and to help shape the encapsulating material. Advantages of the present invention include a reduction in the cost of manufacturing semiconductor components and making the manufacturing process user friendly.

Although certain preferred embodiments and methods have been disclosed herein, it will be apparent from the foregoing disclosure to those skilled in the art that variations and modifications of such embodiments and methods may be made without departing from the spirit and scope of the invention. It is intended that the invention shall be limited only to the extent required by the appended claims and the rules and principles of applicable law.

What is claimed is:

1. A method for manufacturing a semiconductor component, comprising:
providing a first film having first and second major surfaces;
mounting at least one circuit element on the first major surface of the first film, the at least one circuit element having first and second surfaces, the first surface of the at least one circuit element contacting the first major surface of the first film; and
mating a second film to the second surface of the at least one circuit element, the second film having first and second major surfaces, wherein the first major surface of the second film contacts the second surface of the at least one circuit element.

2. The method of claim 1, further including:
removing the first film from the first surface of the at least one circuit element;
forming an encapsulating material on at least the first surface of the at least one circuit element, the encapsulating material having a top surface and a mating surface, the mating surface spaced apart from the at least one circuit element; and
removing the second film from the second surface of the at least one circuit element.

3. The method of claim 1, wherein mounting at least one circuit element on the first major surface of the first film includes mounting a semiconductor wafer on the first film, and further including:
sawing the semiconductor wafer to form a plurality of semiconductor chips;
stretching the first film to separate individual semiconductor chips of the plurality of semiconductor chips from each other; and
wherein mating the second film to the second surface of the at least one circuit element includes joining the second film to at least one of the individual semiconductor chips of the plurality of semiconductor chips.

4. The method of claim 3, further including mating a third film to the mating surface of the encapsulating material, the third film having first and second major surfaces, wherein the first major surface of the third film contacts the mating surface of the encapsulating material.

5. The method of claim 4, further including sawing the encapsulating material to form a plurality of singulated circuit elements.

6. The method of claim 3, wherein sawing the semiconductor wafer to form a plurality of semiconductor chips includes sawing the semiconductor wafer with a first saw blade having a first width and sawing the semiconductor wafer with a second saw blade having a second width.

7. The method of claim 6, wherein the second width is less than the first width.

8. The method of claim 1, wherein mounting the at least one circuit element on the first major surface of the first film includes mounting a circuit element selected from the group of circuit elements consisting of an active circuit element and a passive circuit element.

9. The method of claim 8, wherein the passive circuit element comprises at least one of a resistor, a capacitor, and an inductor.

10. The method of claim 1, wherein mounting the at least one circuit element on the first major surface of the first film includes mounting a plurality of circuit elements on the first major surface of the first film.

11. The method of claim 10, wherein first and second circuit elements of the plurality of circuit elements are different types of circuit elements from each other.

12. The method of claim 1, wherein the first surface of the at least one circuit element is a solderable surface.

13. A method for packaging a circuit element, comprising:
providing a plurality circuit elements mounted to a first adhesive material, wherein the plurality of circuit elements comprises circuit elements having first and second major surfaces, and wherein the first major surfaces of the plurality of circuit elements contact the first adhesive material; and
mating a second adhesive material to the second surfaces of the plurality of circuit elements while the plurality of circuit elements is mounted to the first adhesive material.

14. The method of claim 13, further including:
separating the first adhesive material from the plurality of circuit elements to expose portions of the plurality of circuit elements; and
forming an encapsulating material on the exposed portions of the plurality of circuit elements to form a unitary structure.

15. The method of claim 14, further including:
mounting the unitary structure on a third adhesive material;
separating the second adhesive material from the unitary structure; and
singulating the unitary structure.

16. The method of claim 15, wherein singulating the unitary structure includes singulating a first circuit element of the plurality of circuit elements from a second circuit element of the plurality of circuit elements.

17. The method of claim 16, wherein the first and second circuit elements are one of active circuit elements or passive circuit elements.

18. The method of claim 15, wherein singulating the unitary structure includes singulating first and second circuit elements of the plurality of circuit elements from third and fourth circuit elements of the plurality of circuit elements.

19. The method of claim 18, wherein the first, second, third, and fourth circuit elements are active circuit elements.

20. The method of claim 18, wherein the first and third circuit elements are active circuit elements and the second and fourth circuit elements are passive circuit elements.

21. The method of claim 18, wherein the first and third circuit elements are the same type of circuit elements and the second and fourth circuit elements are the same type of circuit elements.

22. An intermediate structure suitable for use in a semiconductor component, comprising:
a circuit element having first and second major surfaces,
a first film coupled to the first major surface; and
a second film coupled to the second major surface.

23. The semiconductor component of claim 22, wherein the circuit element is one of a passive circuit element or an active circuit element.

24. The semiconductor component of claim 22, wherein a material of the first and second films is a material selected from the group of materials consisting of an acrylate, a polyester, a polyimide, and a composite material.

25. A semiconductor component, comprising:
at least one circuit element having a top surface, a bottom surface, and a side surface; and
an encapsulating material contacting the bottom surface and the side surface, wherein the at least one circuit element is not coupled to a support substrate.

26. The semiconductor component of claim 25, wherein the encapsulating material is not coupled to the support substrate.
